(19) United States
(12) Patent Application Publication
(10) Pub. No.: US 2013/0328461 A1
(43) Pub. Date: Dec. 12, 2013

(54) LATCHING ASSEMBLY AND ELECTRONIC DEVICE USING THE SAME

(71) Applicants: SHENZHEN FUTAIHONG PRECISION INDUSTRY CO., LTD., (US); FIH (HONG KONG) LIMITED, Kowloon (HK)

(72) Inventors: HUAN-CHANG CHUNG, Shindian (TW); GANG YANG, Shenzhen (CN); JING XIA, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/859,524

(22) Filed: Apr. 9, 2013

(30) Foreign Application Priority Data
Jun. 11, 2012 (CN) 2012101898450

(51) Int. Cl. H05K 5/02; H05K 5/00

(52) U.S. Cl. CPC H05K 5/0221; H05K 5/0004
USPC 312/223.1; 403/361

(57) ABSTRACT

A latching assembly is used in an electronic device. The electronic device includes a first housing and a second housing. The latching assembly includes at least a pair of latching elements and at least a pair of locking elements corresponding to the latching elements. Each latching element includes a hook located in the first housing, and a clasp defined in the second housing. Each locking element includes a catch member and a movable member. The catch member locates in the first housing and facing a corresponding hook. The movable member is received between the catch member and the hook. When each hook clasps a corresponding clasp to engage the first housing and the second housing, the movable member moves to the second housing to be caught by the catch member and the hook, allowing the movable member to limit the movement of the hook relative to the clasp.

### CROSS-REFERENCE TO RELATED APPLICATIONS

This application is related to co-pending U.S. Patent Application (Attorney Docket No. US45880), entitled “LATCHING ASSEMBLY AND ELECTRONIC DEVICE USING THE SAME.” Such application has the same assignee as the present application. The above-identified application is incorporated herein by reference.

### BACKGROUND

1. Technical Field

The present disclosure generally relates to latching assemblies, and particularly to a latching assembly used in an electronic device and the electronic device.

2. Description of Related Art

Housings of electronic devices (such as mobile phones) are commonly assembled using screws or by latching structures. However, screws are difficult to be detached when the electronic devices need to be disassembled (to repair or change batteries for example). The latching structure commonly includes conventional hooks. The hooks are configured for engaging in slots of the housing to assemble the electronic device. However, the engagement between the hooks and the slots is prone to loosen when the electronic device is impacted or dropped, which can result in unwanted disassembly.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is an exploded view of a latching assembly used in an electronic device in accordance with an exemplary embodiment, the electronic device includes a first housing and a second housing.

FIG. 2 is a schematic view of the second housing of FIG. 1.

FIG. 3 is an assembly view of the electronic device of FIG. 1.

FIG. 4 is a cross-sectional view of the electronic device of FIG. 3 along line IV-IV.

FIG. 5 is a schematic view of the electronic device of FIG. 4 with the latching assembly in a latched state.

### DETAILED DESCRIPTION

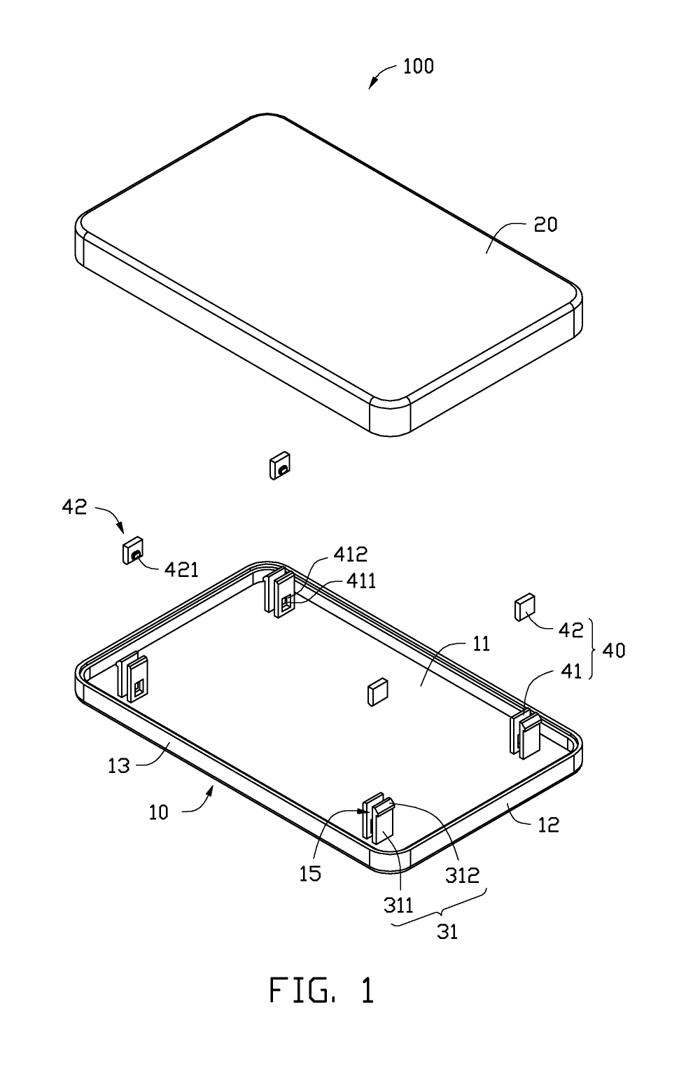

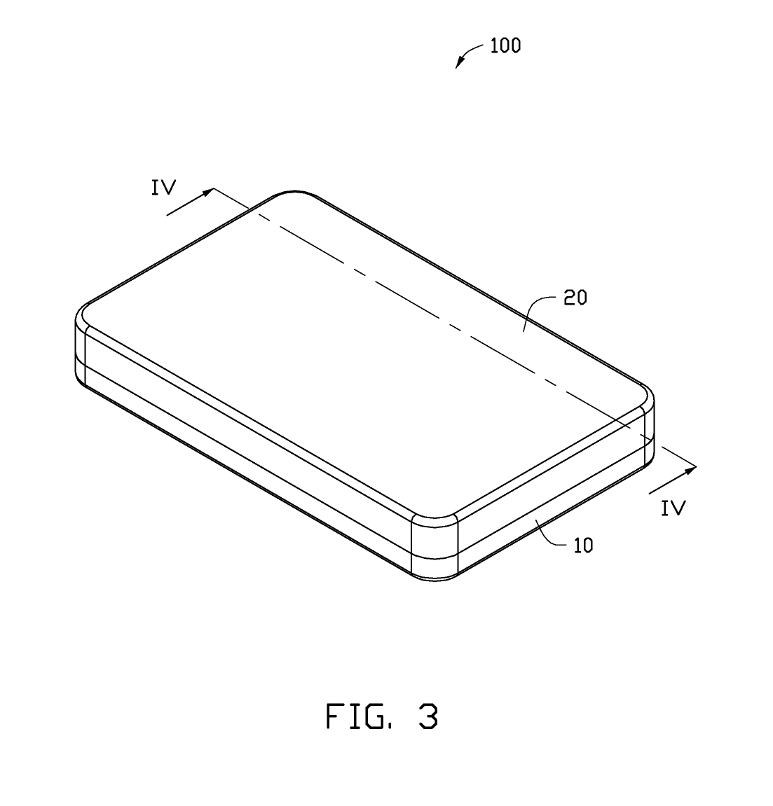

FIGS. 1-3 show a latching assembly used in an electronic device 100 (for example, a mobile phone). The mobile phone is an exemplary application for the purposes of describing details of an exemplary embodiment of a latching assembly. The electronic device 100 includes a first housing 10 and a second housing 20. The latching assembly incorporates the first housing 10 and the second housing 20.

The first housing 10 includes a bottom wall 11, two parallel sidewalls 12, and two parallel end walls 13 perpendicularly protruded from the bottom wall 11. The two sidewalls 12 and the two end walls 13 connect to each other end-to-end.

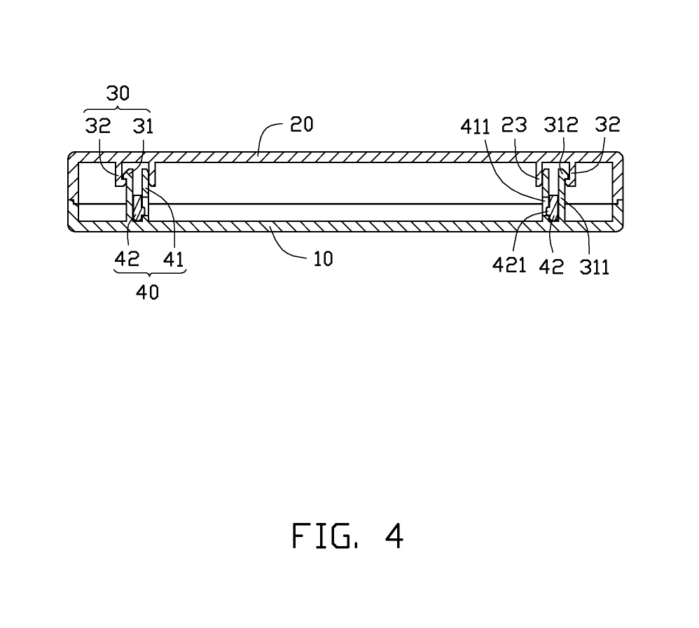

Also referring to FIG. 4, the latching assembly includes at least a pair of latching elements 30 and at least a pair of locking elements 40 corresponding to the latching elements 30. In the embodiment, there are two pairs of latching elements 30 and two pairs of locking elements 40. Each latching element 30 includes a hook 31 located on the bottom wall 11 of the first housing 10, and a clasp 32 defined on the second housing 20. Each locking element 40 includes a catch member 41 and a movable member 42 which can engage with the catch member 41. Each hook 31 clasps a corresponding clasp 32 to engage the first housing 10 to the second housing 20, simultaneously the locking elements 40 engages the hooks 31 with the clasps 32.

FIG. 1 shows that each hook 31 includes a main portion 311 and a hooked portion 312 defined at the free end of the main portion 311. Each hook 31 is located adjacent a sidewall 12 and a corresponding end wall 13. Each catch member 41 is a sheet protruding from the bottom wall 11, and defines a through hole 411 therein at the end adjacent to the bottom wall 11. Each through hole 411 defines a catch wall 412. Each catch member 41 faces a corresponding hook 31. Each catch member 41 and a corresponding hook 31 cooperatively form a first receiving slot 15 therebetween. Each movable member 42 may be a rectangular block made of plastic. Each movable member 42 defines a raised portion 421 on one side, towards the through hole 411. Each movable member 42 is movably received in a corresponding first receiving slot 15, allowing the raised portion 421 to be movably received in the through hole 411 and engages with the catch wall 412.

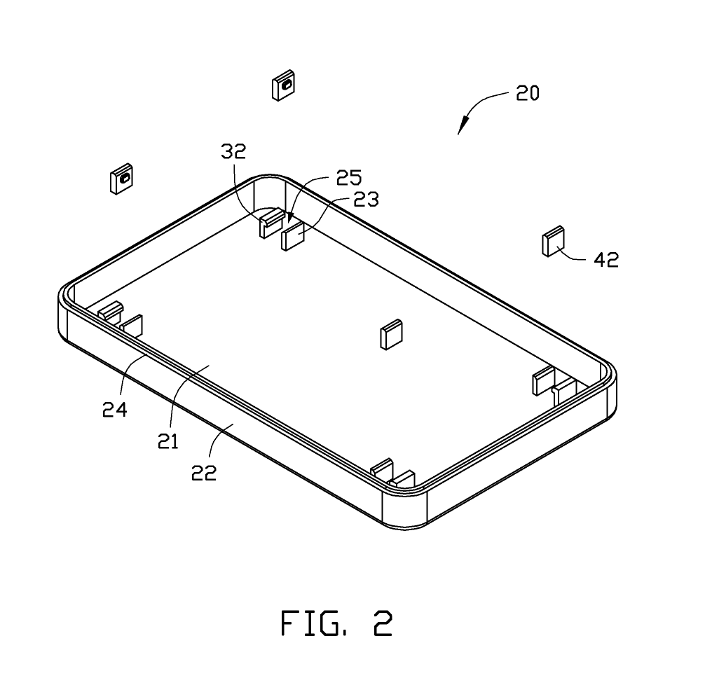

Referring to FIG. 2, the second housing 20 includes a plate 21, and a peripheral wall 22 perpendicularly protruded from the plate 21. Each clasp 32 of the latching element 30 is protruded from the plate 21. Corresponding to each clasp 32, a resisting block 23 is defined on the plate 21, and facing the clasp 32 (also see FIG. 4). Each clasp 32 and a corresponding resisting block 23 cooperatively form a second receiving slot 25 therebetween. Each catch member 41 and the corresponding hook 31 can be partially received in the corresponding second receiving slot 25 such that each first receiving slot 15 communicates with a corresponding second receiving slot 25. Each clasp 32 engages with a hooked portion 312 of a corresponding hook 31 in a second receiving slot 25 to connect the first housing 10 to the second housing 20.

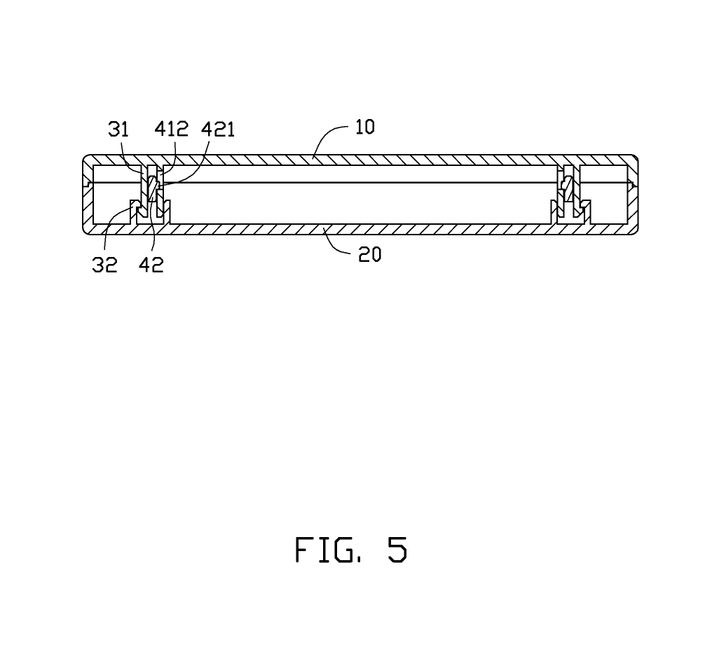

During assembly of the electronic device 100 (see FIG. 4), each movable member 42 is received in a corresponding first receiving slot 15 and contacts the bottom wall 11 of the first housing 10. The second housing 20 is covered on the first housing 10 and pressed towards the first housing 10, allowing each hooked portion 312 and each catch member 41 to be partially received in a corresponding second receiving slot 25, each hooked portion 312 engages with a corresponding clasp 32, and each resisting block 23 resists against a corresponding catch member 41, thereby the first housing 10 and the second housing 20 are connected. Then, together, the first housing 10 and the second housing 20 are rotated 180° (see FIG. 5), making each movable member 42 move in a first receiving slot 15 under gravity along the catch member 41 and the main portion 311 to arrive at the second receiving slot 25, the raised portion 421 of the movable member 42 moves in the through hole 411 to engage the catch wall 412, thereby the movable member 42 is caught between the catch member 41 and the main portion 311 of the hook 31. As a result, movement of the hooked portion 312 relative to the clasp 32 is limited, and the hooked portion 312 can be stably locked by the clasp 32. Even if the electronic device 100 is impacted or dropped, the first housing 10 and the second housing 20 will not easily loosen from each other.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A latching assembly used in an electronic device, the electronic device comprising a first housing and a second housing, the latching assembly comprising:
at least a pair of latching elements, each latching element comprising a hook located in the first housing, and a clasp defined in the second housing; and
at least a pair of locking elements corresponding to the latching elements, each locking element comprising a catch member and a movable member, the catch member locating in the first housing and facing a corresponding hook, the movable member being received between the catch member and the hook;
wherein each hook clasps a corresponding clasp to engage the first housing and the second housing, the movable member is capable of moving towards the second housing to be caught by the catch member and the hook, allowing the movable member to limit the movement of the hook relative to the clasp.

2. The latching assembly as claimed in claim 1, wherein each movable member is a block made of plastic, and defines a raised portion on one side of the movable member, each catch member defines a through hole therein, each through hole defines a catch wall, the raised portion is movably received in the through hole, when the movable member is caught by the catch member and the hook, the raised portion catches the catch wall.

3. The latching assembly as claimed in claim 2, wherein each catch member and a corresponding hook cooperatively form a first receiving slot, the second housing further comprises resisting blocks corresponding to each clasp, each clasp and a corresponding resisting block cooperatively form a second receiving slot, the catch member and the hook insert into the second receiving slot such that the resisting block resists against the catch member, the movable member is capable of moving in the first receiving slot towards the second receiving slot so as to be caught by the catch member and the hook, allowing the movable member to limit the movement of the hook relative to the clasp.

4. The latching assembly as claimed in claim 3, wherein each hook comprises a main portion and a hooked portion defined at the free end of the main portion, the hooked portion engages the clasp in the second receiving slot.

5. An electronic device, comprising:
a first housing;
a second housing; and
a latching assembly, the latching assembly comprising:
at least a pair of latching elements, each latching element comprising a hook located in the first housing, and a clasp defined in the second housing; and
at least a pair of locking elements corresponding to the latching elements, each locking element comprising a catch member and a movable member, the catch member locating in the first housing and facing a corresponding hook, the movable member being received between the catch member and the hook;
wherein each hook clasps a corresponding clasp to engage the first housing and the second housing, the movable member is capable of moving to the second housing to be caught by the catch member and the hook, allowing the movable member to limit the movement of the hook relative to the clasp.

6. The electronic device as claimed in claim 5, wherein each movable member is a block made of plastic, and defines a raised portion on one side of the movable member, each catch member defines a through hole therein, each through hole defines a catch wall, the raised portion is movably received in the through hole, when the movable member is caught by the catch member and the hook, the raised portion catches the catch wall.

7. The electronic device as claimed in claim 6, wherein each catch member and a corresponding hook cooperatively form a first receiving slot, the second housing further comprises resisting blocks corresponding to each clasp, each clasp and a corresponding resisting block cooperatively form a second receiving slot, the catch member and the hook insert into the second receiving slot such that the resisting block resists against the catch member, the movable member is capable of moving in the first receiving slot to the second receiving slot so as to be caught by the catch member and the hook, allowing the movable member to limit the movement of the hook relative to the clasp.

8. The electronic device as claimed in claim 7, wherein the first housing further comprises a bottom wall, two parallel end walls and two end walls perpendicularly protruded from the bottom wall, the sidewalls and the end walls connect each other end-to-end, each hook locates adjacent a sidewall and a corresponding end wall, each catch member is protruded from the bottom wall and faces the hook.

9. The electronic device as claimed in claim 7, wherein the second housing comprises a plate, and a peripheral wall perpendicularly protruded from the plate, each clasp of the latching element is protruded from the plate, each resisting block is protruded from the plate to face a clasp.

10. The electronic device as claimed in claim 7, wherein each hook comprises a main portion and a hooked portion defined at the free end of the main portion, the hooked portion engages the clasp in the second receiving slot to connect the first housing to the second housing.

11. A latching assembly used in an electronic device, the electronic device comprising a first housing and a second housing, the latching assembly comprising:
at least a pair of latching elements, each latching element comprising a hook located in the first housing, and a clasp defined in the second housing; and
at least a pair of locking elements corresponding to the latching elements, each locking element comprising a catch member and a movable member, the catch member locating in the first housing and facing a corresponding hook, the movable member being received between the catch member and the hook;
wherein each hook clasps a corresponding clasp to engage the first housing and the second housing, each movable member is capable of moving to the second housing to be caught by the catch member and the hook, thereby locking a corresponding latching element.

12. The latching assembly as claimed in claim 11, wherein each movable member is a block made of plastic, and defines a raised portion on one side of the movable member, each catch member defines a through hole therein, each through hole defines a catch wall, the raised portion is movably received in the through hole, when the movable member is caught by the catch member and the hook, the raised portion catches the catch wall.

13. The latching assembly as claimed in claim 12, wherein each catch member and a corresponding hook cooperatively form a first receiving slot, the second housing further comprises resisting blocks corresponding to each clasp, each clasp and a corresponding resisting block cooperatively form a second receiving slot, the catch member and the hook insert into the second receiving slot such that the resisting block resists against the catch member, the movable member is capable of moving in the first receiving slot towards the second receiving slot so as to be caught by the catch member and the hook, allowing the movable member to limit the movement of the hook relative to the clasp.

14. The latching assembly as claimed in claim 13, wherein each hook comprises a main portion and a hooked portion defined at the free end of the main portion, the hooked portion engages the clasp in the second receiving slot.
